(19) United States
(12) Patent Application Publication
(10) Pub. No.: US 2007/0207259 A1
(43) Pub. Date: Sep. 6, 2007

(54) Track lithography system with integrated photoresist pump, filter, and buffer vessel

(75) Inventors: Mayur G. Kulkarni, San Jose, CA (US); Y. Sean Lin, Irvine, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/368,118

(22) Filed: Mar. 3, 2006

(51) Int. Cl. C23C 16/52; B05C 11/02; B05C 11/00

(52) U.S. Cl. 427/8; 427/240; 118/52; 118/693; 118/712

(57) ABSTRACT

An integrated photolithography chemical delivery system for a track lithography system. The integrated photolithography chemical delivery system includes a buffer vessel adapted to receive a photolithography chemical from a source volume. The integrated photolithography chemical delivery system also includes a photolithography chemical pump connected to the buffer vessel. The integrated photolithography chemical delivery system further includes a filter connected to the photolithography chemical pump.

### BACKGROUND OF THE INVENTION

The present invention relates generally to the field of substrate processing equipment. More particularly, the present invention relates to the integration of a photolithography chemical dispense pump, filter, and buffer vessel for a semiconductor process chemistry system. Merely by way of example, the method and apparatus of the present invention are used to reduce process variations, thereby improving the accuracy and repeatability of photoresist dispense volumes in a photolithography coating system. The method and apparatus can be applied to other processes for semiconductor substrates, for example those used in the formation of integrated circuits.

Modern integrated circuits contain millions of individual elements that are formed by patterning the materials, such as silicon, metal and/or dielectric layers, that make up the integrated circuit to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to electromagnetic radiation that is suitable for modifying the exposed layer and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various chambers/stations of the track tool and an interface that allows the tool to be operatively coupled to a lithography exposure tool in order to transfer substrates into the exposure tool and receive substrates from the exposure tool after the substrates are processed within the exposure tool.

Over the years there has been a strong push within the semiconductor industry to shrink the size of semiconductor devices. The reduced feature sizes have caused the industry's tolerance to process variability to shrink, which in turn, has resulted in semiconductor manufacturing specifications having more stringent requirements for process uniformity and repeatability. An important factor in minimizing process variability during track lithography processing sequences is to ensure that every substrate processed within the track lithography tool for a particular application has the same “wafer history.” A substrate's wafer history is generally monitored and controlled by process engineers to ensure that all of the device fabrication processing variables that may later affect a device's performance are controlled, so that all substrates in the same batch are always processed the same way.

A component of the “wafer history” is the thickness, uniformity, repeatability, and other characteristics of the photolithography chemistry, which includes, without limitation, photoresist, developer, and solvents. Generally, during photolithography processes, a substrate, for example a semiconductor wafer, is rotated on a spin chuck at predetermined speeds while liquids and gases such as solvents, photoresist (resist), developer, and the like are dispensed onto the surface of the substrate. Typically, the wafer history will depend on the process parameters associated with the photolithography process.

As an example, an inadequate volume of photoresist dispensed during a coating operation will generally impact the uniformity and thickness of coatings formed on the substrate. Therefore, it is desirable to control the volume of the photoresist applied to the substrate with respect to both the accuracy (e.g., total volume per dispense event) and repeatability (e.g., difference in volume per dispense over a series of dispense events) of the dispense process. Present systems do not provide the level of control desirable for current and future track lithography tools. Therefore, there is a need in the art for improved methods and apparatus for controlling the repeatability of photoresist dispense volumes in a photolithography system.

### SUMMARY OF THE INVENTION

According to the present invention techniques related to the field of substrate processing equipment are provided. More particularly, the present invention relates to the integration of a photolithography chemical dispense pump, filter, and buffer vessel for a semiconductor process chemistry system. Merely by way of example, the method and apparatus of the present invention are used to reduce process variations, thereby improving the accuracy and repeatability of photoresist dispense volumes in a photolithography coating system. The method and apparatus can be applied to other processes for semiconductor substrates, for example those used in the formation of integrated circuits.

According to an embodiment of the present invention, an integrated photolithography chemical delivery system for a track lithography system is provided. The integrated photolithography chemical delivery system includes a buffer vessel adapted to receive a photolithography chemical from a source volume. In some embodiments, the photolithography chemical comprises photoresist. Moreover, in other embodiments, the buffer vessel includes a first level sensor and a second level sensor. In a specific embodiment, the first level sensor and the second level sensor are optical sensors. In an alternative embodiment, a hybrid manual/pneumatic flow control valve is coupled to the buffer vessel.

The integrated photolithography chemical delivery system also includes a photolithography chemical pump connected to the buffer vessel. The integrated photolithography chemical delivery system further includes a filter connected to the photolithography chemical pump. In a particular embodiment, the filter comprises a disposable filter.

According to another embodiment of the present invention, a method of operating a photoresist delivery system is provided. The method includes filling a buffer vessel with a first volume of photoresist. The first volume of photoresist is a value greater than 50 milliliters and less than 125 milliliters. The method also includes pumping a second volume of photoresist from the buffer vessel using a pump connected to the buffer vessel. The method further includes filtering the second volume of photoresist using a filter connected to the pump and delivering the second volume of photoresist to a substrate.

According to a alternative embodiment of the present invention, a track photolithography tool is provided. The track lithography tool includes a buffer vessel adapted to receive a photolithography chemical from a source volume and a photolithography chemical pump connected to the buffer vessel. In a specific embodiment, the buffer vessel includes a plurality of optical level sensors. The track lithography tool also includes a filter connected to the photolithography chemical pump. The track lithography tool further includes a spin bowl adapted to rotate a substrate and a photolithography chemical dispense apparatus coupled to the filter and adapted to dispense the photolithography chemical onto a surface of the substrate.

Many benefits are achieved by way of the present invention over conventional techniques. For example, integration of the dispense pump, filter, and buffer vessel reduces or eliminates the need for additional fittings, thereby minimizing the probability of crystallization. Moreover, integration of components as provided by embodiments of the present invention provides equivalent head heights and liquid line lengths between the pump, filter, and buffer vessel, thereby increasing the pump-to-pump repeatability of dispense processes. Additionally, this integration reduces pump setup time in the field. An additional benefit provided by embodiments of the present invention is a reduction in the dispense chemistry system footprint, enabling an increase in the number of pumps packaged per chemical drawer. Depending upon the embodiment, one or more of these benefits, as well as other benefits, may be achieved. These and other benefits will be described in more detail throughout the present specification and more particularly below in conjunction with the following drawings.

### BRIEF DESCRIPTION OF THE DRAWINGS

FIG. 1 is a simplified plan view of an embodiment of a track lithography tool according to an embodiment of the present invention;

FIG. 2A is a simplified schematic illustration of a photolithography chemical dispense apparatus according to an embodiment of the present invention;

FIG. 2B is a simplified schematic illustration of a photolithography chemical dispense apparatus according to another embodiment of the present invention;

FIG. 3 is a simplified perspective view illustration of an integrated dispense pump, filter, and buffer vessel according to an embodiment of the present invention;

FIG. 4 is a simplified schematic illustration of a level sensing device according to an embodiment of the present invention;

FIG. 5 is a graph illustrating cyclical variation of dispense volume produced using a particular method of dispense;

FIG. 6 is a flowchart illustrating a method of operating an integrated photolithography chemical dispense apparatus according to an embodiment of the present invention; and

FIG. 7 is a simplified flowchart illustrating a method of operating an integrated photolithography chemical dispense apparatus according to another embodiment of the present invention.

### DETAILED DESCRIPTION OF SPECIFIC EMBODIMENTS

According to the present invention techniques related to the field of substrate processing equipment are provided. More particularly, the present invention relates to the integration of a photolithography chemical dispense pump, filter, and buffer vessel for a semiconductor process chemistry system. Merely by way of example, the method and apparatus of the present invention are used to reduce process variations, thereby improving the accuracy and repeatability of photoresist dispense volumes in a photolithography coating system. The method and apparatus can be applied to other processes for semiconductor substrates, for example those used in the formation of integrated circuits.

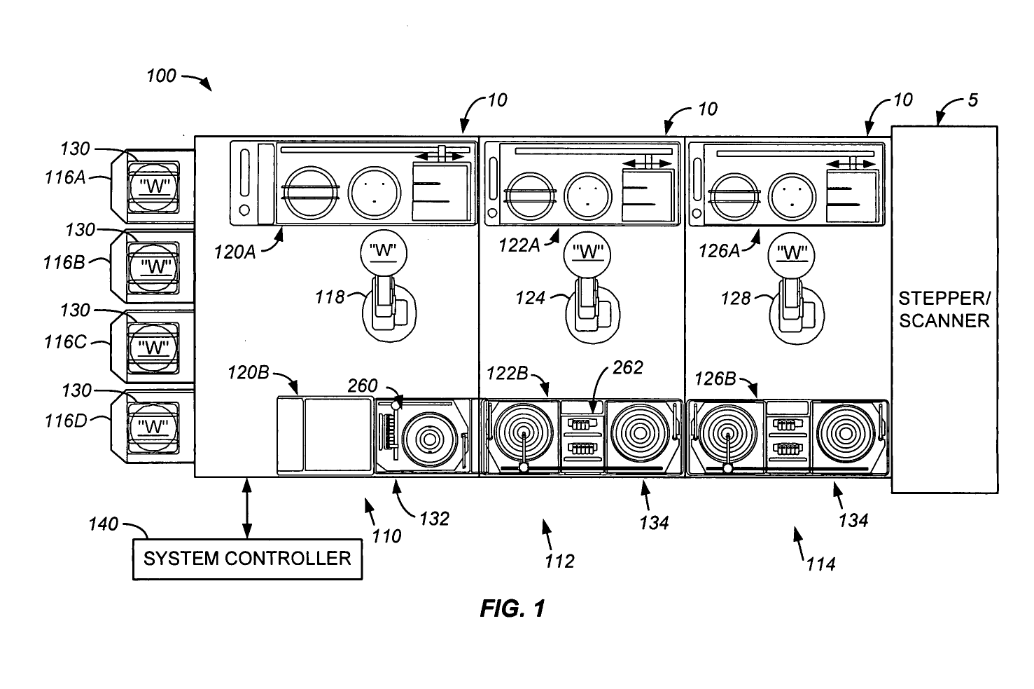

FIG. 1 is a plan view of an embodiment of a track lithography tool 100 in which the embodiments of the present invention may be used. As illustrated in FIG. 1, track lithography tool 100 contains a front end module 110 (sometimes referred to as a factory interface or FI), a central module 112, and a rear module 114 (sometimes referred to as a scanner interface). Front end module 110 generally contains one or more pod assemblies or FOUPS (e.g., items 116A-D), a front end robot 118, and front end processing racks 120A and 120B. The one or more pod assemblies 116A-D are generally adapted to accept one or more cassettes 130 that may contain one or more substrates or wafers, “W,” that are to be processed in track lithography tool 100.

Central module 112 generally contains a first central processing rack 122A, a second central processing rack 122B, and a central robot 124. Rear module 114 generally contains first and second rear processing racks 126A and 126B and a back end robot 128. Front end robot 118 is adapted to access processing modules in front end processing racks 120A, 120B; central robot 124 is adapted to access processing modules in front end processing racks 120A, 120B, first central processing rack 122A, second central processing rack 122B and/or rear processing racks 126A, 126B; and back end robot 128 is adapted to access processing modules in the rear processing racks 126A, 126B and in some cases exchange substrates with a stepper/scanner 5.

The stepper/scanner 5, which may be purchased from Canon USA, Inc. of San Jose, Calif., Nikon Precision Inc. of Belmont, Calif., or ASML US, Inc. of Tempe Ariz., is a lithographic projection apparatus used, for example, in the manufacture of integrated circuits (ICs). The scanner/stepper tool 5 exposes a photosensitive material (resist), deposited on the substrate in the cluster tool, to some form of electromagnetic radiation to generate a circuit pattern corresponding to an individual layer of the integrated circuit (IC) device to be formed on the substrate surface.

Each of the processing racks 120A, 120B; 122A, 122B; and 126A, 126B contain multiple processing modules in a vertically stacked arrangement. That is, each of the processing racks may contain multiple stacked integrated thermal units 10, multiple stacked coater modules 132, multiple stacked coater/developer modules with shared dispense 134 or other modules that are adapted to perform the various processing steps required of a track photolithography tool. As examples, coater modules 132 may deposit a bottom antireflective coating (BARC); coater/developer modules 134 may be used to deposit and/or develop photoresist layers and integrated thermal units 10 may perform bake and chill operations associated with hardening BARC and/or photoresist layers.

In one embodiment, a system controller 140 is used to control all of the components and processes performed in the cluster tool 100. The controller 140 is generally adapted to communicate with the stepper/scanner 5, monitor and control aspects of the processes performed in the cluster tool 100, and is adapted to control all aspects of the complete substrate processing sequence. In some instances, controller 140 works in conjunction with other controllers, such as a post exposure bake (PEB) controller, to control certain aspects of the processing sequence. The controller 140, which is typically a microprocessor-based controller, is configured to receive inputs from a user and/or various sensors in one of the processing chambers and appropriately control the processing chamber components in accordance with the various inputs and software instructions retained in the controller's memory. The controller 140 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 140 determines which tasks are performable in the processing chamber(s). Preferably, the program is software readable by the controller 140 and includes instructions to monitor and control the process based on defined rules and input data.

It is to be understood that embodiments of the invention are not limited to use with a track lithography tool such as that depicted in FIG. 1. Instead, embodiments of the invention may be used in any track lithography tool including the many different tool configurations described in U.S. application Ser. No. 11/112,281, entitled “Cluster Tool Architecture for Processing a Substrate” filed on Apr. 22, 2005, which is hereby incorporated by reference for all purposes and including configurations not described in the above referenced application.

Generally, track lithography tools are used to dispense precise amounts of expensive lithography chemicals onto substrates to form thin, uniform coatings. For modern lithography processes, the volumes of chemicals, such as photoresist, dispensed per event are small, for example, 1 milliliter (ml). In some lithography processes, other volumes, for example, ranging from about 0.5 ml to about 5 ml are utilized. The volume of chemical dispensed, the flow rate during the dispense operation, among other variables, are controlled during the process of dispensing the lithography chemicals, for example, photoresist. Preferably, control of the dispense operations in a track lithography tool provide actual dispensed volumes with an accuracy of ±0.02 ml and repeatability from dispense event to dispense event of 3σ<0.02 ml.

A wide variety of photolithography chemicals are utilized in track lithography tools according to embodiments of the present invention. For example, photoresist, bottom anti-reflective coating (BARC), top anti-reflective coating (TARC), top coat (TC), Safier, and the like are dispensed onto the substrate. In some embodiments, after the selected chemical is dispensed, the substrate is spun to create a uniform thin coat on an upper surface of the substrate. Generally, to provide the levels of uniformity desired of many photolithography processes, dispense events start with a solid column of chemical. The flow rate is generally set at a predetermined rate as appropriate to a particular chemical deliver process.

As the dispense event is terminated, the fluid is typically drawn back into the dispense line, sometimes referred to as a suck-back process utilizing a suck-back valve. In some track lithography tools, the fluid is brought back into the dispense line about 1-2 mm from the end of the dispense nozzle, forming a reverse meniscus. This suck-back process prevents the lithography chemicals from dripping onto the substrate and prevents the chemicals from drying out inside the nozzle.

For some photolithography chemical dispense applications, the dispense pump and the filter used as portions of the chemical dispense apparatus are connected through hoses, fittings, and other plumbing components. The fluid present in such plumbing components provides dead volumes in which the photoresist may crystallize. The presence of crystallized photoresist in the dispense system may adversely impact the repeatability achieved for the thickness and dispense rates of coatings. Moreover, variations in the length of liquid lines or hoses may result in differences in head heights and pressures, also adversely impacting film properties. Thus, embodiments of the present invention provide integrated photolithography chemical delivery systems that address such issues.

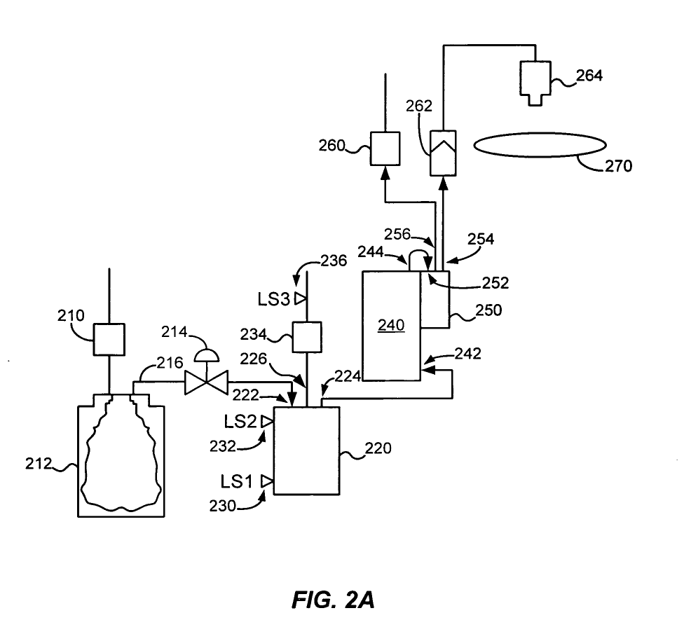

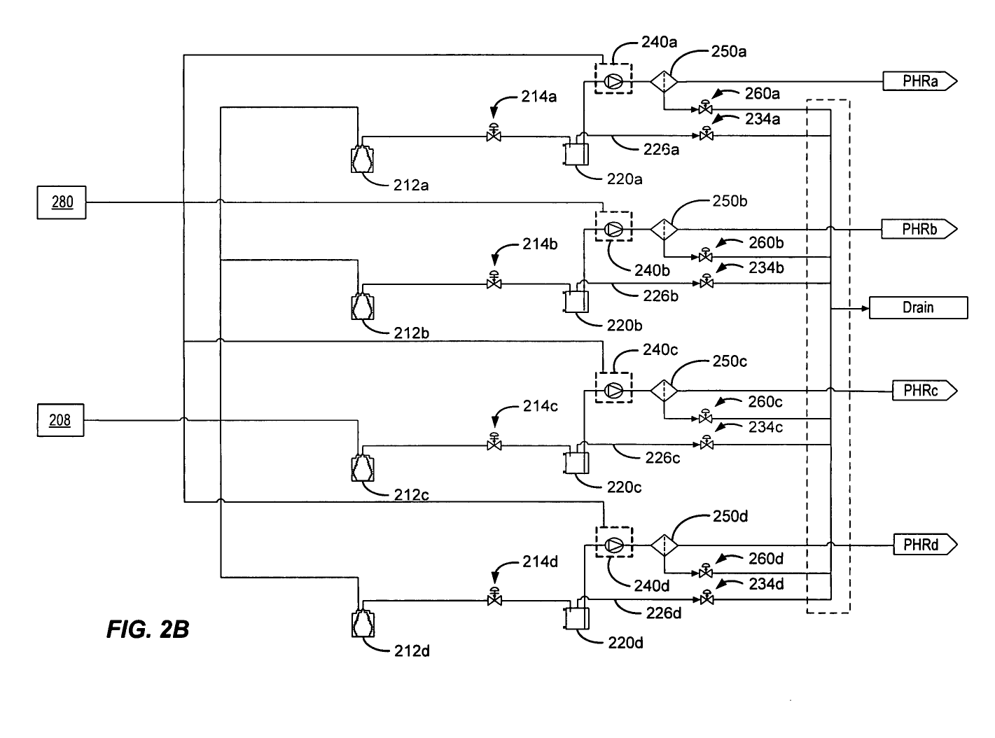

FIG. 2A is a simplified schematic illustration of a photolithography chemical dispense apparatus according to an embodiment of the present invention. A pressure valve 210 is coupled to a source bottle 212 containing the photolithography chemical to be dispensed onto the substrate surface. In an embodiment, the source bottle is a NOWPak® container available from ATMI, Inc., Danbury, Conn. The source bottle is coupled to a flow control valve 214 and adapted to regulate the flow of the photolithography chemical in fluid line 216.

In a specific embodiment of the present invention, the flow control valve 214 is a hybrid manual/pneumatic valve adapted to provide control of the flow of photolithography chemicals in an operating mode and to provide a manual shut-off feature in a service mode. The hybrid valve includes a pneumatically controlled portion which is operable to open or close the valve upon activation by a pressurized fluid, for example, air. Under computer control, the pressurized fluid is applied to control ports, enabling a system operator to control the flow of fluid from the source bottle 212 to the buffer vessel 220. Utilizing process recipes, as described in more detail below, predetermined amounts of photoresist or other photolithography chemicals are transferred from the source bottle to the buffer vessel. In some embodiments, the amount of photoresist transferred in a single transfer process is sufficient to coat an entire lot of wafers. In other embodiments, the predetermined amount of photoresist or other photolithography chemicals are small, as little as 1 ml.

Additionally, the hybrid valve includes a manually controlled portion which is also operable to open or close the valve, generally an action performed by a service technician. In an embodiment, the hybrid valve includes a lock-out/tag-out feature. Generally, a lock-out feature utilizes a key or other locking mechanism coupled to the valve. During servicing of the photolithography dispense system, the technician is able to manually close and lock the valve to prevent flow of photolithography chemicals during service procedures. A tag-out feature provides a mechanism for the technician to tag or label the valve, providing information to other technicians regarding a service procedure.

The lock-out/tag-out features provided by the hybrid valve provide a measure of safety and security for embodiments of the present invention. As the lock-out feature overrides computer actuation of the valve, a service technician or other operator is able to assure that the flow of photolithography chemicals through the hybrid valve is prevented, even if the pneumatically controlled portion of the valve is opened. Thus, safety of service personnel, as well as cost savings from wasted photolithography chemicals is provided by embodiments of the present invention. One of skill in the art will appreciate the safety features associated with the lock-out/tag-out features and recognize many variations, modifications, and alternatives. Hybrid valves as utilized in embodiments of the present invention include a ¼″ S300 thin wall, manual override pneumatic valve with a 4 mm orifice and a PTFE wet surface, part number LYX-1334, available from CKD Corporation of Kasugai City, Japan.

Buffer vessel 220 is illustrated in FIG. 2A and includes an input port 222, an output port 224, and a vent port 226. The input port 222 of the buffer vessel 220 is coupled to the fluid line 216. As illustrated in FIG. 2A, the buffer vessel includes a number of level sensors, for example, level sensor LS1 (230) and level sensor LS2 (232). As described more fully below, the level sensors are utilized to regulate the volume of photolithography chemical present in the buffer vessel 220.

The vent port 226 of the buffer vessel is coupled to a vent valve 234 and a level sensor LS3 (236). Level sensor LS3 serves to monitor the level of fluid passing through the vent valve 234. The output port 224 of the buffer vessel is coupled to input port 242 of dispense pump 240. As illustrated in FIG. 2A, a filter 250 is integrated with the dispense pump 240 and the output port 244 of the dispense pump is coupled to an input port 252 of the filter 250. A vent port 256 and an output port 254 are provided on the filter 250 and, as illustrated in FIG. 2A, a vent valve 260 is coupled to the vent port 256. A shut off/suck-back valve 262 is coupled to the fluid line running from the output port 254 of the filter. From valve 262, the photolithography chemical is delivered to substrate 270 through dispense nozzle 264. As will be evident to one of skill in the art, apparatus adapted to chuck and spin the substrate are not illustrated for purposes of clarity. Furthermore, additional dispense systems provided according to embodiments of the present invention and adapted to provide photolithography chemicals, e.g., multi-nozzle systems, are not illustrated for purposes of clarity.

FIG. 2B is a simplified schematic illustration of a photolithography chemical dispense apparatus according to another embodiment of the present invention. As illustrated in FIG. 2B, a number of source bottles 212a, 212b, 212c, and 212d are connected to a source of photolithography chemicals 208. Generally, pressurized sources and control valves are utilized to force the flow of chemicals into the source bottles 212a-212d. Valves 214a-214d are utilized to control the flow of fluid from the source bottles to the buffer vessels 220a-220d. In some embodiments, valves 214a-214d are operated under computer control to deliver predetermined amounts of the photolithography chemicals to the buffer vessels 220a-220d. As described in relation to FIG. 2A, in some embodiments, the valves 214a-214d are hybrid manual/pneumatic valves adapted to provide control of the flow of photolithography chemicals in an operating mode and to provide a manual shut-off feature in a service mode.

In an embodiment, the photolithography chemicals include photoresist. As illustrated in FIG. 2B, photoresist is delivered through pumps 240a-240d and filters 250a-250d to dispense nozzles PHRa-PHRd. In the embodiment of the present invention illustrated in FIG. 2B, pressurized source 280, for example, a valved source of nitrogen is utilized in the operation of pumps 240. In alternative embodiments, nitrogen is used to perform electrical purging, wherein in other embodiments, the use of nitrogen is optional. Vent valves 234 and 260 are associated with buffer vessels 220 and filter 250. In an embodiment, vent lines connected to the output of the vent valves run to a drain. One of ordinary skill in the art would recognize many variations, modifications, and alternatives. As described more fully throughout the specification, and more particularly below, the buffer vessel, pump, and filter are integrated for each photolithography chemical dispense line according to embodiments of the present invention.

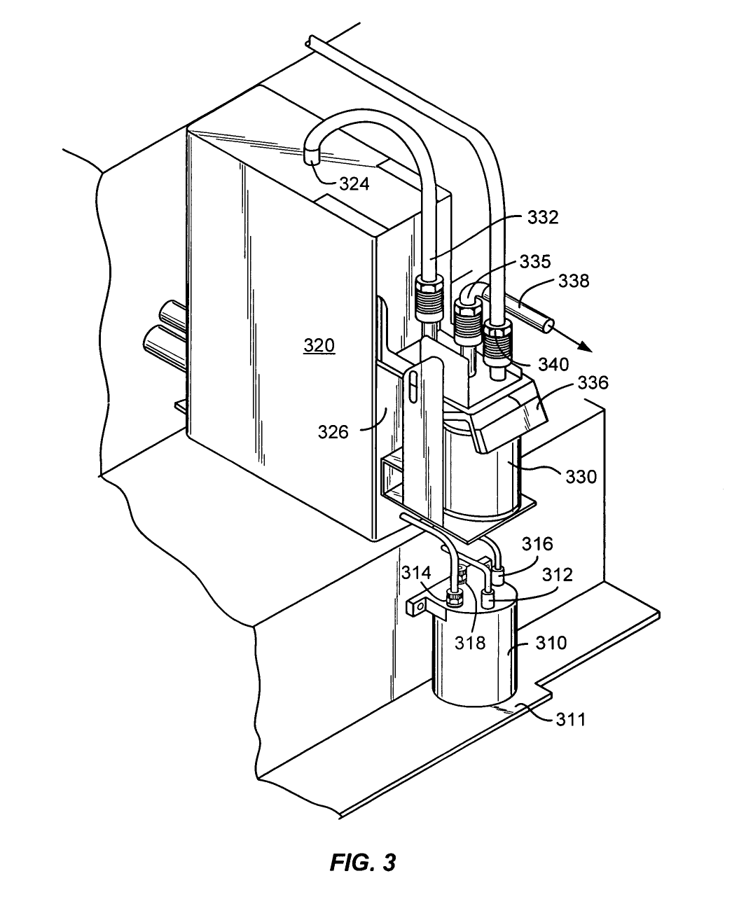

FIG. 3 is a simplified perspective view illustration of an integrated dispense pump, filter, and buffer vessel according to an embodiment of the present invention. In the embodiment illustrated in FIG. 3, buffer vessel 310 is mounted on a support member 311. In some embodiments, the support member is mounted in connection with the pump enclosure 326. In a particular embodiment, support for the buffer vessel is provided by plates mounted on the pump. In alternative embodiments, the support member 311 is mounted in connection with larger support members associated with the dispense system. One of ordinary skill in the art would recognize many variations, modifications, and alternatives.

The input to the buffer vessel 310 is represented by the fluid line coupled to the input port 312, which receives a fluid such as photoresist, from a source vessel, for example, a photoresist source bottle (not shown), (e.g., such as illustrated by reference number 212 in FIG. 2). Additional valves and other fluid control devices positioned between the source bottle and the buffer vessel are not illustrated for purposes of clarity. According to some embodiments of the present invention, the supply line from the source vessel is welded to the input port 312 of the buffer vessel, eliminating fittings that couple the supply line to the buffer vessel.

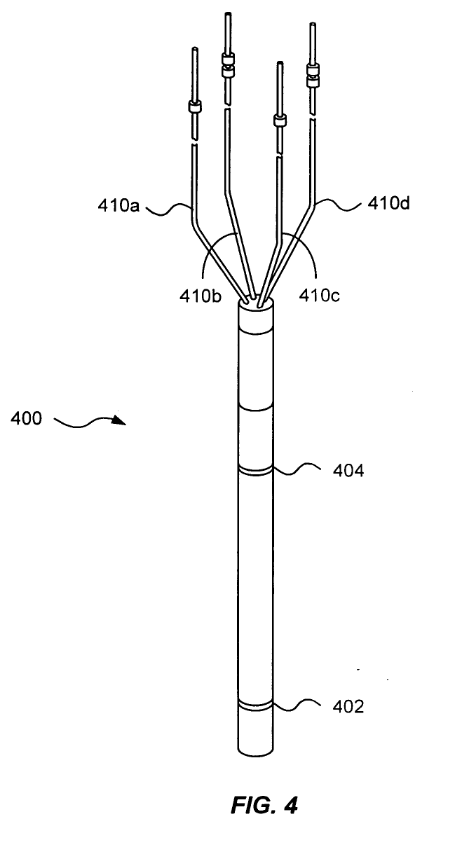

Buffer vessel 310 also includes an output port 314, a vent port 316, and a sensor port 318 for a level sensing device. As described more fully below, the level sensing devices utilized in embodiments the present invention, include a number of level sensors to moderate the level of photoresist contained in the buffer vessel. Control systems utilized to operate embodiments of the present invention utilize the level sensors to regulate the flow of photoresist through the input port 312. Referring to FIG. 4, a simplified schematic illustration of a level sensing device according to an embodiment of the present invention is provided. Optical fibers 410a-410d are illustrated in FIG. 4 and are utilized in some embodiments to provide optical inputs and outputs for the level sensing device 400.

For example, referring to FIG. 4, level sensor 402 provides an indication of a lower limit for fluid level in the buffer vessel 310. Level sensor 404 provides an indication of an upper limit for fluid level in the buffer vessel. In a particular embodiment according to the present invention, the level sensing device 400 is a SUNX CFD0083 sensor available from Ramco Innovations of West Des Moines, Iowa. As illustrated in FIG. 4, level sensor 402 comprises an optical sensor including a source of optical radiation and a detector integrated into a single sensor aperture. For example, in an embodiment, light is delivered into the level sensor through fiber 410a and is emitted from the aperture illustrated by reference number 402. When the liquid in the buffer vessel makes contact with the level sensor aperture, light reflected off the sensor/liquid interface is collected by fiber 410b and delivered to a sensor controller. As will be evident to one of skill in the art, level sensor 404, utilizing fibers 410c and 410d operates using a similar mechanism.

As described more fully below, control of the fluid level in the buffer vessel provides for improved repeatability and availability of photoresist for a batch of substrates or wafers. For example, in some semiconductor lithography processes, lots of 25 wafers are processed using track lithography tools provided by embodiments of the present invention.

In embodiments of the present invention, level sensors 402 and 404 are utilized to maintain the volume of photolithography chemical in the buffer vessel in a range of predetermined values. In a specific embodiment, level sensor 420 is coupled to a “bottle empty alarm” indicating that the buffer vessel is reaching a level at which it is advisable to stop wafer processing. In some embodiments, level sensor 402 indicates that a minimum volume of fluid is present in the buffer vessel, for example, 10 ml. In alternative embodiments, the minimum level varies, for example, from 5 ml to about 20 ml. Of course, the particular minimum volume will depend on the particular application. One of ordinary skill in the art would recognize many variations, modifications, and alternatives.

Level sensor 404 is used in embodiments of the present invention in a control system adapted to fill the buffer vessel with photolithography chemicals. In a specific embodiment, the level sensor 404 is used to maintain the volume in the buffer vessel at a constant level, for example 80 ml. In other embodiments, the level sensor 404 is positioned to correspond to a fill level of 60 ml. Generally, the level is selected to provide enough fluid in the buffer vessel to complete processing of the current lot of semiconductor wafers. As with the minimum volume, the particular maximum volume will depend on the particular application.

In some embodiments, a control system is used to maintain the level of dispense fluid in a region adjacent the level sensor 404. For example, when the system detects that the level in the buffer vessel has dropped to a level below level sensor 404, additional dispense fluid is provided from the source bottle 212 to increase the fluid level in the buffer vessel. In some embodiments, the amount of fluid transferred is fixed, whereas in other embodiments, the fluid level is variable, filling the buffer vessel until an indication from level sensor 404 is received by the control system.

Referring once again to FIG. 3, buffer vessel 310 is connected to dispense pump 320 in order to deliver the dispense fluid from the buffer vessel to the pump. The input to the pump receives the photolithography chemical from an output port 314 of the buffer vessel. In an embodiment, the buffer vessel interfaces to the pump through machined stubs, welded tubes, pass-through compression fittings, or the like. In a specific embodiment, machined stubs are fabricated from Teflon® PFA. In another specific embodiment, a compression fitting is used to couple the fluid line running from the buffer vessel output port to the input port of the dispense pump. In a particular embodiment utilizing pumps manufactured by Koganei Corporation of Tokyo, Japan, the input line of the dispense pump comprises an input tube that is connected to the buffer vessel through a compression fitting. Generally, the end of the input tube farthest from the dispense pump is cut at an angle of about 45° and installed in the buffer vessel to maintain a predetermined distance from the end of the input tube and the bottom of the buffer vessel. In other embodiments, other angles are utilized. For example, the distance from the end of the input tube to the bottom of the buffer vessel ranges from about 3 mm to about 4 mm in some embodiments. The angled bottom of the input tube prevents the end of the tube from forming a seal with the bottom of the buffer vessel.

As illustrated in FIG. 3, a vent port 316 is provided on the buffer vessel and is connected to a vent valve, not shown. Additionally, the output port located on the upper surface of the dispense pump is coupled to the input port of the filter 330 through fluid line 332. In a particular embodiment, the filter is a disposable filter, such as a Pall PhotoKleen™ EZD-3 series filter available from Pall Microelectronics of East Hills, N.Y. In an alternative embodiment (not shown), the filter is an IMPACT® 2 disposable filter available from Mykrolis Corporation of Billerica, Mass. One of ordinary skill in the art would recognize many variations, modifications, and alternatives.

In some embodiments of the present invention, the filter 330 is directly connected to the pump 320 by fittings. Moreover, in the embodiment illustrated in FIG. 3, filter bracket 336 is mechanically mounted to the pump enclosure 326. Utilizing embodiments of the present invention, a system operator is able to replace the disposable filter using the filter bracket. As will be evident to one of skill in the art, the filter bracket can be positioned in a change-out position, in which the filter can be disconnected from the pump. The filter bracket also has an operating position, in which the filter is connected to the pump. Generally, the actuation of the filter bracket is performed by an operator. One of ordinary skill in the art would recognize many variations, modifications, and alternatives.

Filtered photoresist flows out of the filter output port 335 as indicated by the arrow pointing out of filter output line 338. Vent port 340 is connected to a vent valve (not shown) to provide for venting of the filter 330. In some embodiments, the vents for the buffer vessel and the pump are coupled to drain. One of ordinary skill in the art would recognize many variations, modifications, and alternatives.

Although FIG. 3 illustrates a particular physical orientation of the various dispense system components, embodiments of the present invention are not limited to this particular physical orientation. Alternative embodiments of the present invention provide orientations in which the position of the buffer vessel, the pump, and the filter are modified. For example, in some embodiments, the filter bracket and the buffer vessel are integrated as part of the pump enclosure. In alternative embodiments, multiple pumps are connected to a single buffer vessel. One of ordinary skill in the art would recognize many variations, modifications, and alternatives.

Some embodiments of the present invention utilize methods for calibrating dispense volume using a variety of system measurements. Examples of these calibration methods are discussed in additional detail in co-pending and commonly assigned U.S. patent application Ser. No. ______ (Attorney Docket No. 016301-063000US), filed on ______ and incorporated in its entirety herein for all purposes.

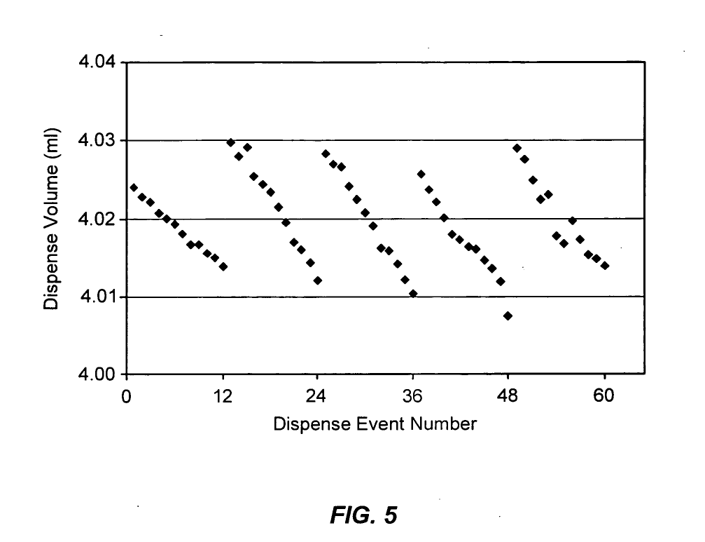

FIG. 5 is a graph illustrating cyclical variation of dispense volume produced using a particular method of dispense. In order to collect the data illustrated in FIG. 5, a source vessel was coupled to a dispense pump. The dispense pump was operated to provide five dispense cycles, each dispense cycle comprising approximately 12 dispense events. As illustrated in FIG. 5, approximately 60 dispense events were performed. The source vessel was refilled to approximately a constant level at the end of each dispense cycle.

Generally, a trend of decreasing dispense volume per dispense event is observed during each of the dispense cycles. For example, in the first dispense cycle, the dispense volume decreases from about 4.025 ml to about 4.015 ml, a decrease of 0.01 ml. While not being limited to any particular theory, it is believed that a reason for the variation in dispense volume during the dispense cycles is a change in liquid level in the source bottle from one dispense event to another dispense event.

As the dispense chemical was transferred from the source vessel into the dispense pump, the liquid level in the source vessel decreased. Thus, as illustrated in FIG. 5, one explanation for the generally linear decrease in dispense volume is the decrease in the liquid level in the source vessel. One consequence of the liquid level change in the source vessel from dispense to dispense is that the dispense accuracy and repeatability are adversely affected. Accordingly, embodiments of the present invention maintain the fluid level in the buffer vessel within a predetermined window to improve the accuracy and repeatability of dispense operations. It should be noted that the variations illustrated in FIG. 5 may explain a variety of observations related to dispense operations. For example, some dispense operations are characterized by bottle-to-bottle variations in which replacement of an empty source bottle with a full source bottle results in variations in dispense volumes. While not being limited to any particular theory, it is believed that a reason for this bottle-to-bottle variation may be the difference in head pressure due to the differing fluid levels in an empty and full source bottle. As explained more fully below, embodiments of the present invention solve such problems through the use of at least a buffer vessel.

Embodiments of the present invention utilize a buffer vessel coupled to a dispense pump to reduce the variation in dispense volume as illustrated in FIG. 5. In a particular embodiment, a level sensing device, such as that illustrated in FIG. 4, is used to monitor the liquid level in the buffer vessel. In some embodiments, a control algorithm is used to maintain the liquid level in the buffer vessel within a predetermined window, thereby reducing variation in dispense volumes as a function of the number of dispense events or operations.

For example, in an embodiment, the liquid level in the buffer vessel is monitored using a level sensing device with a plurality of level sensors. Merely by way of example, level sensor 404, as illustrated in FIG. 4, is used in an embodiment to regulate the fluid level at approximately a constant level in the buffer vessel. Level sensor 402 is utilized to perform an alarm monitoring function. Thus, in this embodiment, level sensor 404 is utilized to detect liquid level and filling of the buffer vessel is initiated when the fluid level drops below the level sensor 404. Filling is continued until a predetermined amount of fluid enters the buffer vessel. In other embodiments, filling is performed for a predetermined time. In some embodiments, the predetermined amount is enough to raise the fluid level to that of the level sensor 404. A configurable stop-delay is included according to a particular embodiment to avoid frequent filling and to assure that the liquid level is maintained within a predetermined window or range. In alternative embodiments, additional level sensors are utilized to provide level sensing indications at additional buffer vessel liquid levels.

In some embodiments, the filling process is initiated and terminated in a manner that maintains the fluid level within the buffer vessel in a predetermined range. For example, in a particular embodiment, the fluid level within the buffer vessel is maintained within ¼″ of a predetermined level. Thus, an indication is received from level sensor 404 that the level of fluid in the buffer vessel has decreased to a level below the sensor. A filling process is initiated before the level drops more than a selected amount, for example, ¼″. The filling of the buffer vessel is initiated to increase the fluid level and the filling process is monitored, using level sensor 404 or other means, to terminate the filling process after a predetermined amount of fluid, a predetermined amount of time, or other metric has been satisfied. Using this process, the fluid level in the buffer vessel is maintained at an approximately constant level, for example, at a fill level within ¼″ as a function of time. In other embodiments, other windows, such as ⅛″, ⅓″, or ½″ windows are utilized. One of ordinary skill in the art would recognize many variations, modifications, and alternatives.

Although FIG. 4 illustrates the use of optical level sensors, this is not required by embodiments of the present invention. In other embodiments, other sensors are utilized. For instance, ultrasound sensors, capacitive sensors, mechanical sensors such as mechanical float sensors, and other types of sensors are utilized in alternative embodiments. One of ordinary skill in the art would recognize many variations, modifications, and alternatives.

As will be evident to one of skill in the art, a predetermined liquid level window in the buffer vessel is provided by embodiments of the present invention. Merely by way of example, windows ranging from fractions of a milliliter to several milliliters are provided by the fill processes with a configurable stop-delay. The particular liquid volume associated with the liquid level window will depend on the particular application. For example, the preferable liquid level window will depend on the geometry of the buffer vessel. As an example, a buffer vessel characterized by a larger cross-sectional area measured in the plane of the upper surface of the liquid will generally be associated with a larger liquid level window in comparison with a buffer vessel with a smaller cross-sectional area. For a buffer vessel with a larger cross-sectional area, the change in the height of the upper surface of the liquid varies more slowly as a given volume of liquid is dispensed. Thus, in some embodiments, the sensitivity to changes in the volume of fluid in the buffer vessel is reduced as a result of the buffer vessel geometry, allowing the use of larger liquid level windows in some applications. In some embodiments, the liquid level window is equivalent to about 0.25 inches. In other embodiments, the liquid level window is equivalent to other linear measures depending on the particular buffer vessel geometry and applications.

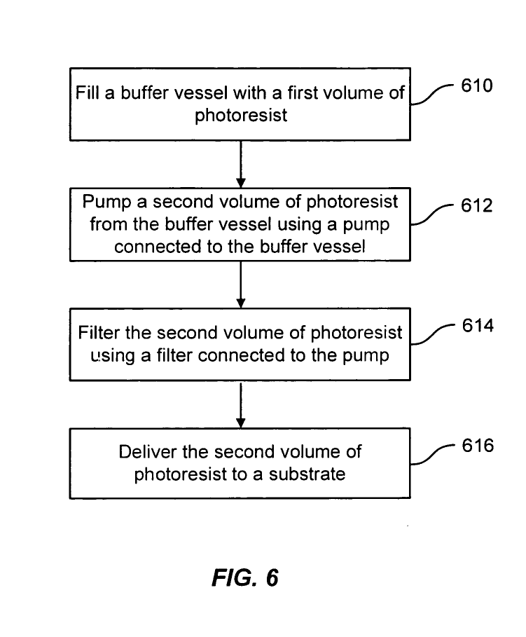

FIG. 6 is a simplified flowchart illustrating a method of operating an integrated photolithography chemical dispense apparatus according to an embodiment of the present invention. As illustrated in FIG. 6, a buffer vessel is filled with a first volume of photoresist (610). In some embodiments, level sensors or other detectors are utilized to monitor the volume of photoresist dispensed into the buffer vessel. For example, a particular embodiment utilizes two level sensors adapted to provide an indication of the buffer level volume from a minimum value of 50 ml to a maximum value of 125 ml. Accordingly, in a specific embodiment of the present invention a first volume of photoresist ranging from 0 ml to 75 ml is delivered to the buffer vessel to fill the buffer vessel. In alternative embodiments, the positions of the level sensors are modified to provide indication at different fluid levels. Moreover, additional level sensors are utilized in other embodiments to provide additional fluid level information to a system controller.

A second volume of photoresist is pumped from the buffer vessel utilizing a pump connected to the buffer vessel (612). As illustrated in FIG. 3, embodiments of the present invention provide a direct connection between the buffer vessel and the dispense pump. Integrated packaging, as illustrated in FIG. 3, provides constant liquid line lengths between the buffer vessel and the pump, increasing the dispense reliability and reducing the dispense system setup time in the field. According to embodiments of the present invention, the second volume of photoresist is a predetermined value. Generally, the second volume of photoresist is less than the first volume of photoresist, providing multiple substrate dispense operations for each buffer vessel fill operation. For example, the second volume of photoresist ranges from about 0.5 ml to about 5.0 ml in some embodiments. In a particular embodiment, the second volume of photoresist is about 1.0 ml.

The second volume of photoresist is filtered (614) using a filter connected to the pump. In some embodiments, the filter is a disposable filter mechanically mounted to the pump enclosure using a filter bracket. The second volume of photoresist is delivered to a substrate (616), for example, a semiconductor wafer.

Although the method illustrated in FIG. 6 provides a method of operating a photoresist dispense system, including dispensing photoresist onto a substrate, embodiments of the present invention are not limited to photoresist dispense operations. Alternative embodiments provide for dispense of additional photolithography chemicals, including, bottom anti-reflective coating (BARC), top anti-reflective coating (TARC), top coat (TC), Safier, and the like.

It should be appreciated that the specific steps illustrated in FIG. 6 provide a particular method of operating an integrated photolithography chemical dispense apparatus according to an embodiment of the present invention. Other sequence of steps may also be performed according to alternative embodiments. For example, alternative embodiments of the present invention may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular applications. One of ordinary skill in the art would recognize many variations, modifications, and alternatives.

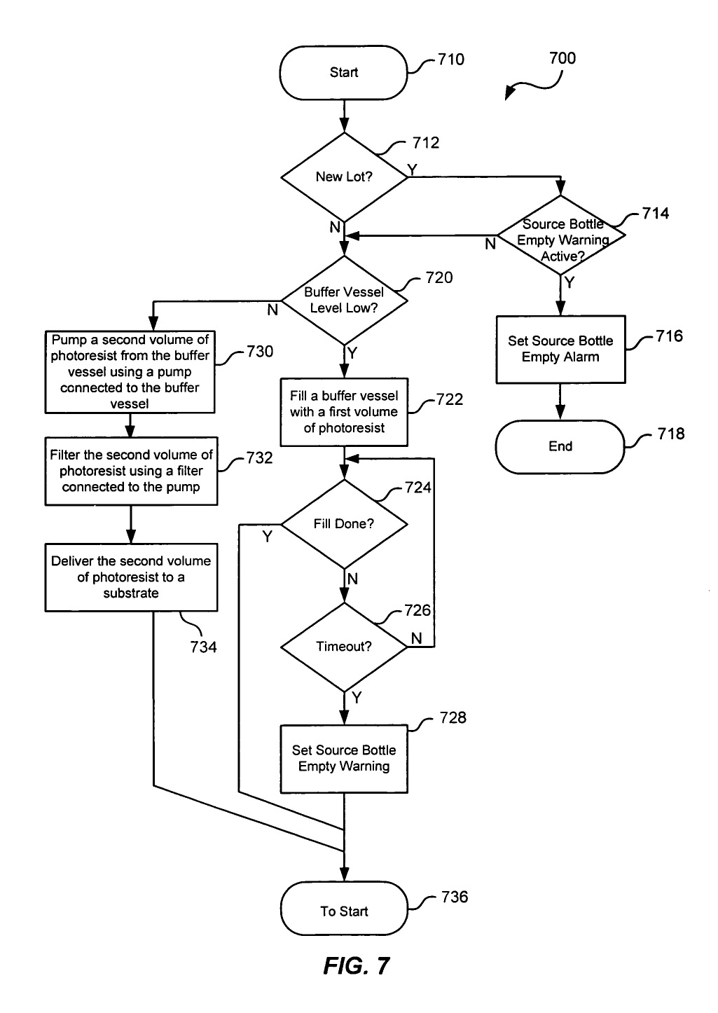

FIG. 7 is a simplified flowchart illustrating a method of operating an integrated photolithography chemical dispense apparatus according to another embodiment of the present invention. As illustrated in FIG. 7, and described more fully below, multiple lots of substrates are processed, each lot involving multiple dispense operations. The method 700 of operating an integrated photolithography chemical dispense apparatus illustrated in FIG. 7 begins at step 710. Decision point 712 is utilized to determine if a new lot of substrates is to be processed. If an additional lot of substrates is to be processed, a determination is made (714) if the source bottle empty warning is active. If this warning is not active, the method proceeds to step 720. If, on the other hand, the source bottle empty warning is active, an alarm is triggered (716) indicating that the source bottle is empty. The process is terminated at step 718 until the source bottle is refilled.

In step 720, a determination is made if the buffer vessel level is below a predetermined value. In some embodiments, this determination defines a “low” level for the buffer vessel. In a particular embodiment, the predetermined value is 10 ml. In another particular embodiment, the predetermined value is 25 ml. Of course, embodiments of the present invention are not limited to these particular values. If the level in the buffer vessel is determined to be low, the buffer vessel is filled with the first volume of photoresist (722). The volume of photoresist dispensed into the buffer vessel is monitored until a fill level is reached (724). In a specific embodiment of the present invention, the first volume of photoresist ranges from 0 ml to about 75 ml. Upon successful completion of the fill operation, the method proceeds (736) to start step 710. If the level in the buffer vessel does not reach the fill level within a predetermined time limit, a timeout signal is generated (726) and a warning is generated that the source bottle is empty (728). Generally, the buffer vessel should contain sufficient chemical to complete the processing of the current lot.

If at decision point 720, a determination is made that the buffer vessel level is not low, a second volume of photoresist is pumped from the buffer vessel utilizing a pump connected to the buffer vessel (730). According to embodiments of the present invention, the second volume of photoresist is a predetermined value. As discussed below, generally, the second volume of photoresist is less than the first volume of photoresist, providing multiple substrate dispense operations for each buffer vessel fill operation. For example, the second volume of photoresist ranges from about 0.5 ml to about 5.0 ml in some embodiments. In a particular embodiment, the second volume of photoresist is about 1.0 ml. The second volume of photoresist is filtered (732) using a filter connected to the pump. In some embodiments, the filter is a disposable filter mechanically mounted to the pump enclosure using a filter bracket. The second volume of photoresist is delivered to a substrate (734), for example, a semiconductor wafer.

After the dispense operation is completed, the method proceeds (736) to start step 710. Once again, a determination is made (712) regarding whether additional substrates are present in a lot of substrates. For example, in some embodiments, 25 substrates are grouped in a first lot and 25 substrates are grouped in a second lot. Of course, these examples are merely provided by way of example, and the present invention is not limited to particular lot sizes or a particular number of lots.

As will be evident to one of skill in the art, the first volume of photoresist used to fill the buffer vessel will vary as a function of the number of substrates in a lot and the particular process for the substrates in the lot. Thus, the first volume used to fill the buffer vessel in step 722 may be different than the initial first volume discussed above. One of ordinary skill in the art would recognize many variations, modifications, and alternatives.

Additionally, as will be evident to one of skill in the art, the second volume of photoresist pumped from the buffer vessel will vary as a function of the dispense process for a particular substrate. Thus, the second volume pumped after continuing along process path including steps 730 through 734 may be different than the initial second volume discussed above. One of ordinary skill in the art would recognize many variations, modifications, and alternatives.

Merely by way of example, in a specific embodiment, the buffer vessel is filled in view of the number of substrates and the particular processes utilized for the substrates in an upcoming lot. In this particular embodiment of the present invention, a determination is made by a controller of the volume of photoresist to be dispensed for the upcoming lot. If, for example, the total volume of photoresist is 25 ml, the buffer vessel is filled to a level of 50 ml. Thus, after the processing of the upcoming lot, a volume of 25 ml remains in the buffer vessel. The amount of fluid present in the buffer vessel is generally selected to provide process accuracy and repeatability.

According to another embodiment of the present invention, filling of the buffer vessel is not performed while liquids such as photoresist are pumped from the buffer vessel (see, for example, step 730 in FIG. 7). As will be evident to one of skill in the art, temporally separating the buffer vessel fill process and the pumping operations avoids disturbance from the fill process during the pumping operation.

It should be appreciated that the specific steps illustrated in FIG. 7 provide a particular method of operating an integrated photolithography chemical dispense apparatus according to another embodiment of the present invention. Other sequence of steps may also be performed according to alternative embodiments. For example, alternative embodiments of the present invention may perform the steps outlined above in a different order. Moreover, the individual steps illustrated in FIG. 7 may include multiple sub-steps that may be performed in various sequences as appropriate to the individual step. Furthermore, additional steps may be added or removed depending on the particular applications. One of ordinary skill in the art would recognize many variations, modifications, and alternatives.

While the present invention has been described with respect to particular embodiments and specific examples thereof, it should be understood that other embodiments may fall within the spirit and scope of the invention. The scope of the invention should, therefore, be determined with reference to the appended claims along with their full scope of equivalents.

What is claimed is:

1. An integrated photolithography chemical delivery system for a track lithography system, the integrated photolithography chemical delivery system comprising:
a buffer vessel adapted to receive a photolithography chemical from a source volume;
a photolithography chemical pump connected to the buffer vessel; and
a filter connected to the photolithography chemical pump.

2. The system of claim 1 wherein the photolithography chemical comprises photoresist.

3. The system of claim 1 wherein the buffer vessel comprises a first level sensor and a second level sensor.

4. The system of claim 3 wherein the first level sensor and the second level sensor are optical sensors.

5. The system of claim 3 wherein the first level sensor and the second level sensor are analog sensors.

6. The system of claim 3 wherein the first level sensor indicates a buffer vessel fluid volume of greater than or equal to 70 milliliters.

7. The system of claim 3 wherein the second level sensor indicates a buffer vessel fluid volume of less than or equal to 10 milliliters.

8. The system of claim 7 wherein the filter is mounted in a filter bracket attached to the pump.

9. The system of claim 1 further comprising a hybrid manual/pneumatic flow control valve coupled to the buffer vessel.

10. A method of operating a photoresist delivery system, the method comprising;
filling a buffer vessel with a first volume of photoresist, wherein the first volume of the photoresist is a value less than 80 milliliters;
pumping a second volume of photoresist from the buffer vessel using a pump connected to the buffer vessel;
filtering the second volume of photoresist using a filter connected to the pump; and
delivering the second volume of photoresist to a substrate.

11. The method of claim 10 wherein the second volume is a value ranging from 0.5 milliliters to 5.0 milliliters.

12. The method of claim 11 wherein the second volume is about 1.0 milliliters.

13. The method of claim 10 wherein a hybrid manual/pneumatic flow control valve is coupled to the buffer vessel.

14. The method of claim 10 wherein the filter is mounted in a filter bracket attached to the pump.

15. The method of claim 10 further comprising:
monitoring a fluid level in the buffer vessel;
detecting a decrease in the monitored fluid level below a predetermined level;
initiating fluid flow into the buffer vessel; and
terminating fluid flow in to the buffer vessel, wherein terminating fluid flow is performed to maintain the fluid level in the buffer vessel within a predetermined window of the predetermined level.

16. The method of claim 15 wherein the predetermined window is ¼ inch.

17. A track photolithography tool comprising:
a buffer vessel adapted to receive a photolithography chemical from a source volume;
a photolithography chemical pump connected to the buffer vessel;
a filter connected to the photolithography chemical pump;
a spin bowl adapted to rotate a substrate; and
a photolithography chemical dispense apparatus coupled to the filter and adapted to dispense the photolithography chemical onto a surface of the substrate.

18. The track lithography tool of claim 17 wherein the buffer vessel comprises a plurality of level sensors adapted to provide an indication of an alarm level and an operating level.

19. The track lithography tool of claim 17 wherein the plurality of level sensors are optical sensors.

20. The track lithography tool of claim 17 further comprising a hybrid manual/pneumatic flow control valve coupled to the buffer vessel.
